(19) United States
(12) Patent Application Publication
(10) Pub. No.: US 2017/0322601 A1
(43) Pub. Date: Nov. 9, 2017

(54) APPARATUS FOR CONFIGURING A MEMORY DRIVE DEVICE

(71) Applicant: R-STOR INC., Saratoga, CA (US)

(72) Inventor: Giovanni COGLITORE, Saratoga, CA (US)

(21) Appl. No.: 15/585,939

(22) Filed: May 3, 2017

Related U.S. Application Data
(60) Provisional application No. 62/331,753, filed on May 4, 2016.

(51) Int. Cl. G06F 1/18; G06F 1/20; G11C 5/02; G06F 13/40

(52) U.S. Cl. CPC G06F 1/181; G11C 5/025; G06F 13/4022; G06F 1/184; G06F 1/186; G06F 1/20

(57) ABSTRACT

Certain embodiments may relate to configuring a memory drive device. An apparatus may be provided. The apparatus may include an enclosure having at least one open side, a plurality of memory cards secured within the enclosure, an indicator in communication with the plurality of memory cards, and a motherboard connected to the plurality of memory cards. The plurality of memory cards may be exposed to the at least one open side, and may be suspended over each other. Further, the indicator may be configured to indicate an operating status of each of the plurality of memory cards.

### CROSS REFERENCE TO RELATED APPLICATION

This application claims priority to U.S. Provisional Application No. 62/331,753 filed on May 4, 2016. The entire contents of the above-referenced provisional application in hereby incorporated by reference.

### BACKGROUND

### Field

Certain embodiments of the present invention may relate to configuring a memory drive device.

### Description of the Related Art

Digital information has been traditionally stored on hard disk drives. Hard disk drives may store digital information using at least one rotating disk that includes magnetic material. The digital information may written onto and read from the at least one rotating disk by a magnetic head. Because traditional hard disk drives typically use moving/mechanical components, these traditional hard disks would be prone to mechanical failure after extended use. Therefore, solid-state drives have become an increasingly popular replacement for hard disk drives. Solid-state drives are generally considered to be storage devices that store digital information using integrated circuit assemblies, without use of moving/mechanical components.

### SUMMARY

According to an embodiment, an apparatus may include an enclosure. The enclosure may include at least one open side. The apparatus may also include a plurality of memory cards. The plurality of memory cards are secured within the enclosure, the memory cards are exposed to the at least one open side, and the memory cards are suspended over each other. The apparatus may also include an indicator. The indicator is in communication with the memory cards. The indicator indicates whether any of the memory cards needs to be replaced. The apparatus may also include a motherboard. The motherboard is connected to the plurality of memory cards. The apparatus may also include a fan.

In the apparatus, memory components of the memory cards may be arranged in parallel to an airflow direction of an airflow provided by the fan to dissipate heat.

In the apparatus, the indicator indicates whether any of the memory cards need to be replaced via lights.

In the apparatus, the memory cards include solid-state memory components.

In the apparatus, the memory cards include spinning/rotating memory components.

In the apparatus, the memory cards include memory components, and the memory components comprise m.2 drives.

### BRIEF DESCRIPTION OF THE DRAWINGS

For proper understanding of the invention, reference should be made to the accompanying drawings, wherein:

FIG. 1 illustrates an example drive device, in accordance with certain embodiments of the present invention.

FIG. 2 illustrates an assembled example drive device, in accordance with certain embodiments of the present invention.

FIG. 3 illustrates an example memory card, in accordance with certain embodiments of the present invention.

FIG. 4 illustrates an overview of a system implemented by a drive device, in accordance with certain embodiments of the present invention.

FIG. 5 illustrates an apparatus in accordance with certain embodiments of the invention.

FIG. 6 illustrates another example drive device, in accordance with another embodiment of the present invention.

### DETAILED DESCRIPTION

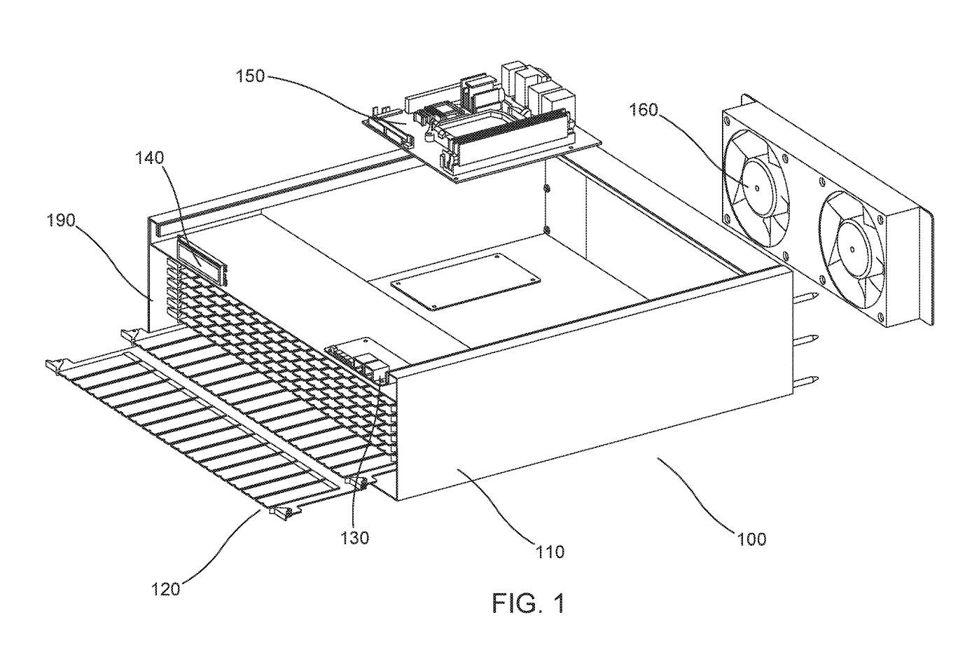

Certain embodiments of the present invention may relate to configuring a memory drive device. FIG. 1 illustrates an example drive device, in accordance with certain embodiments of the present invention. Certain embodiments may include a drive device 100 where different components are contained within an enclosure 110. With certain embodiments, the enclosure 110 can have at least one open face/side. For example, enclosure 110 of FIG. 1 has an open side 190. Enclosure 110 of certain embodiments may be configured in accordance with standardized form factors. For example, the length, width, and height of enclosure 110 may be configured in increments of 1 U, 2 U, 3 U, etc. 1 U may correspond to 1.75 inches (44.45 mm).

Certain embodiments may allow a plurality of memory devices 120 to be inserted and secured within enclosure 110. For example, certain embodiments may be configured such that the plurality of memory cards 120 can be easily inserted and secured within enclosure 110 via open side 190. The memory cards may be suspended over each other, such that a space is provided between each inserted memory card. The space can allow air flow to pass over and/or below the memory cards in order to aid in heat dissipation, as described in more detail below. In the example shown in FIG. 1, nine memory devices/cards are inserted and secured within the enclosure.

With certain embodiments, each of the memory cards/devices can be easily inserted and removed. The drive device can provide hot-plug capability, such that the memory devices may be removed from the enclosure without powering down the power provided to the overall drive device.

In the example of FIG. 1, drive device 100 includes space for nine memory cards 120 to be inserted and secured. Certain embodiments may also include an Input-Output (IO) indicator 130 that is in communication with the memory cards 120. The IO indicator may know the operating status of each memory card, at each point in time. After one or more memory cards 120 are inserted into the drive device 100, IO indicator 130 can provide a visual indication that reflects the operation of the memory cards. For example, the IO control indicator can brighten certain lights to indicate a normal operating status or other lights to indicate that a problem has occurred. With these lights, a user may readily determine whether one or more memory cards is malfunctioning, by merely looking at the lighting of IO control indications.

With certain embodiments, a system status display 140 can provide further details regarding the operating status of the memory cards 120. For example, if a problem occurs, the system status display 140 can indicate which memory card is experiencing a problem. In contrast to the previous approaches, embodiments of the present invention may allow a user to easily identify problematic memory components (via IO indicator 130 or via system status display 140, for example) and may allow the user to easily remove/replace the problematic memory elements by using the open face 190.

The drive device 100 of certain embodiments may also include a motherboard 150 that manages the communication between the memory cards and the computing system into which the drive device 100 is inserted. In other words, motherboard 150 can act as an interface between memory cards 120 and the external environment. For example, the motherboard 150 can perform the functionality of a switching layer, a processing layer (with one or more processors), and/or a router. In one embodiment, the motherboard may be a Mini-ITX motherboard.

The motherboard 150 can perform the function of a router by routing data to and from the memory cards. Data can be routed to and from the external computing system. For example, data can be routed from drive device 100 to other drive devices.

The drive device 100 may also include a fan device 160 that aids in the dissipation of the heat that is generated by the plurality of memory cards 120. The components on the memory cards 120 can be arranged in a direction that is parallel to the airflow of the fan device. For example, if the components of the memory cards 120 are m.2 drives, the length of the m.2 drives can be arranged in parallel to the direction of the airflow. Therefore, when fan device 160 causes airflow to move across the enclosure, the airflow can dissipate heat that is generated by memory cards 120. In one embodiment, the components of the memory cards 120 can be solid-state memory components. In another embodiment, the components of the memory cards 120 can be spinning/rotating memory components. Other embodiments can include a combination of solid-state memory and spinning/rotating memory.

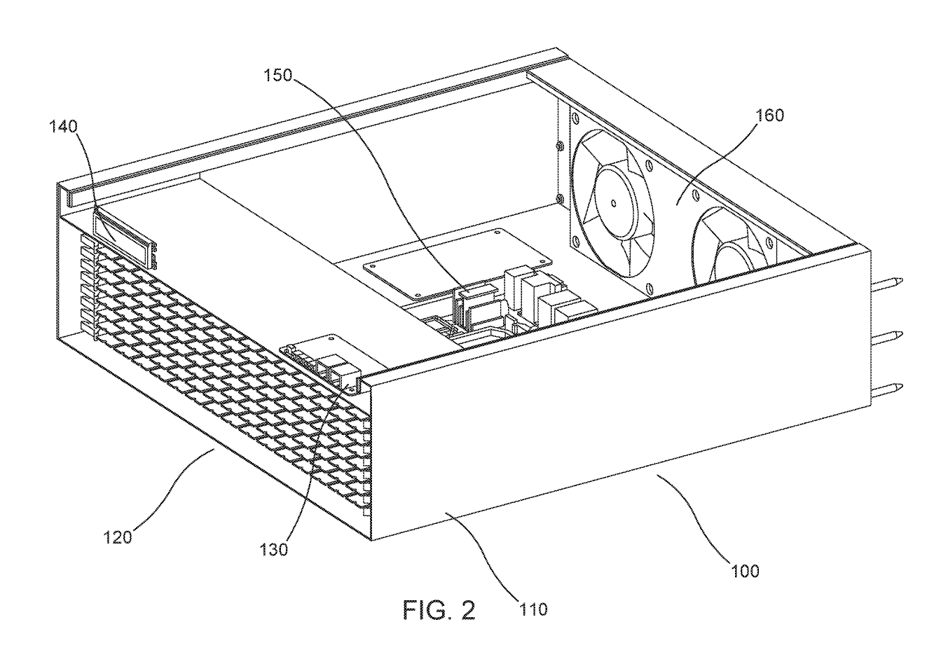

FIG. 2 illustrates an assembled example drive device, in accordance with certain embodiments of the present invention. FIG. 2 illustrates an assembled drive device 100. The assembled drive device 100 integrates the functionality of the memory cards 120, IO indicator 130, a system status display 140, a motherboard 150, and/or a fan device 160.

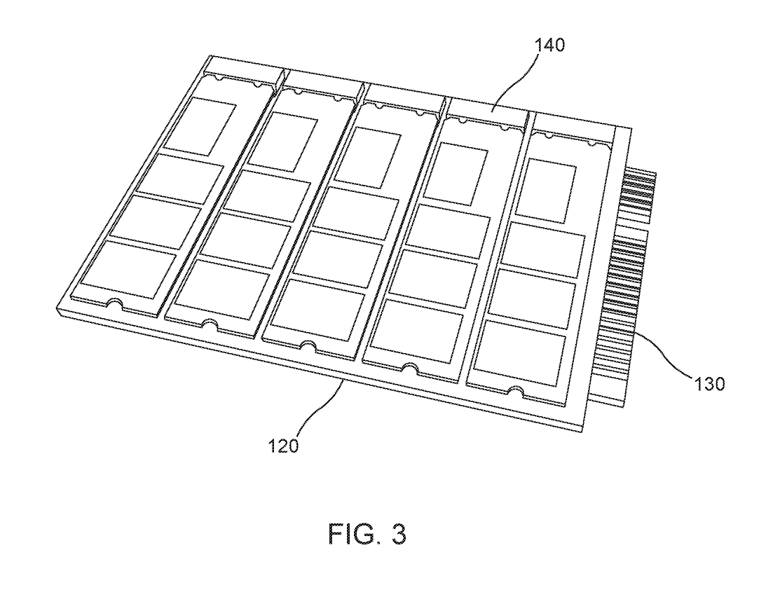

FIG. 3 illustrates an example memory card 120, in accordance with certain embodiments of the present invention. Each memory card 120 can include a plurality of separate memory components. In the example of FIG. 3, each memory card can include 5 m.2 memory components. Memory card 120 can also include one or more connection points or interfaces (130, 140) that allow the memory card 120 to be inserted and secured within drive device 110.

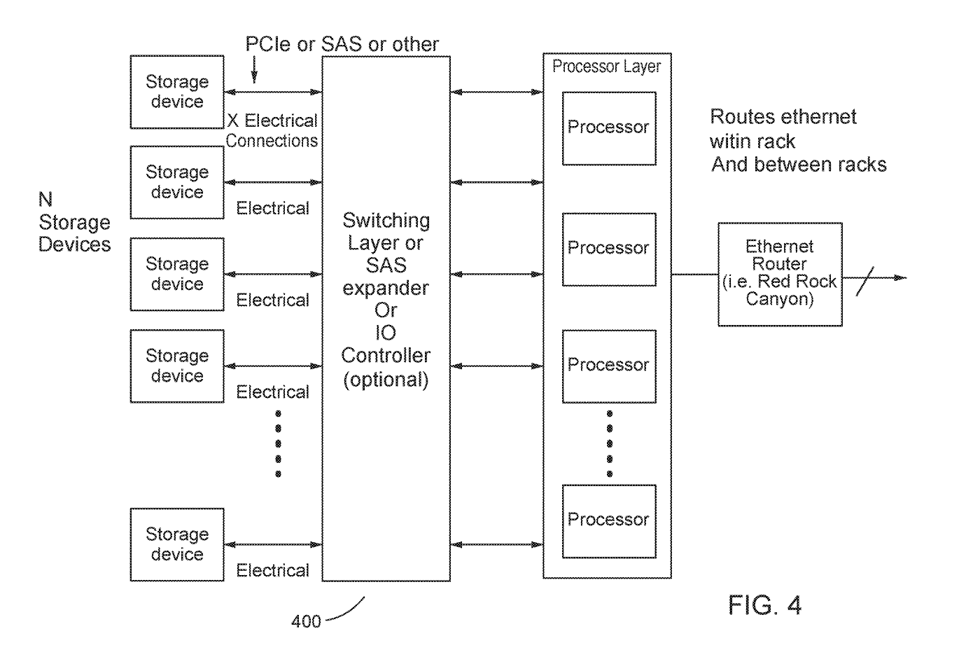

FIG. 4 illustrates an overview of a system implemented by a drive device, in accordance with certain embodiments of the present invention. FIG. 4 illustrates an overview of the system 400 implemented by drive device 100. System 400 may include storage devices that are implemented by the components of memory cards 120. As discussed above, these components may by solid-state drives. The storage devices may be electrically connected to a switching layer. The switching layer may be implemented by motherboard 150. System 400 may also include a processor layer that is also implemented by motherboard 150. Further, system 400 may also include an Ethernet routing functionality that is also implemented by motherboard 150. The Ethernet routing functionality may enable data to be communicated to and from memory cards 120, and to and from other racks of drive devices.

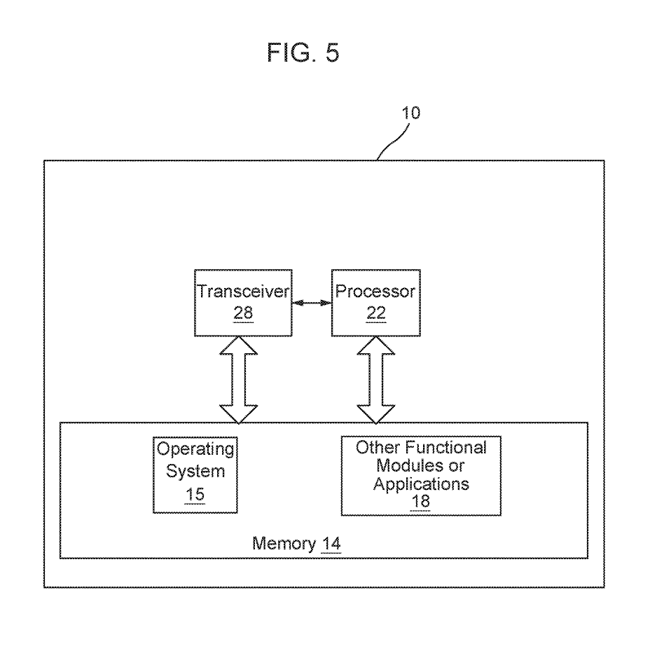

FIG. 5 illustrates an apparatus 10 according to certain embodiments of the present invention. In an embodiment, apparatus 10 may be a device that performs one or more functions on motherboard 150. Apparatus 10 may also be configured to operate as a switching layer, processor layer, and/or a processor layer. In another embodiment, apparatus 10 may be a device implemented on one or more of the memory cards 120, which allows memory cards 120 to communicate with motherboard 150.

Apparatus 10 includes a processor 22 for processing information and executing instructions or operations. Processor 22 may be any type of general or specific purpose processor. While a single processor 22 is shown in FIG. 5, multiple processors may be utilized according to other embodiments. In fact, processor 22 may include one or more of general-purpose computers, special purpose computers, microprocessors, digital signal processors (“DSPs”), field-programmable gate arrays (“FPGAs”), application-specific integrated circuits (“ASICs”), and processors based on a multi-core processor architecture, as examples.

Apparatus 10 further includes a memory 14, coupled to processor 22, for storing information and instructions that may be executed by processor 22. Memory 14 may be one or more memories and of any type suitable to the local application environment, and may be implemented using any suitable volatile or nonvolatile data storage technology such as a semiconductor-based memory device, a magnetic memory device and system, an optical memory device and system, fixed memory, and removable memory. For example, memory 14 can be comprised of any combination of random access memory (“RAM”), read only memory (“ROM”), static storage such as a magnetic or optical disk, or any other type of non-transitory machine or computer readable media. The instructions stored in memory 14 may include program instructions or computer program code that, when executed by processor 22, enable the apparatus 10 to perform tasks as described herein.

Apparatus 10 may also include one or more antennas (not shown) for transmitting and receiving signals and/or data to and from apparatus 10. Apparatus 10 may further include a transceiver 28 that modulates information on to a carrier waveform for transmission by the antenna(s) and demodulates information received via the antenna(s) for further processing by other elements of apparatus 10. In other embodiments, transceiver 28 may be capable of transmitting and receiving signals or data directly.

Processor 22 may perform functions associated with the operation of apparatus 10 including, without limitation, precoding of antenna gain/phase parameters, encoding and decoding of individual bits forming a communication message, formatting of information, and overall control of the apparatus 10, including processes related to management of communication resources.

In an embodiment, memory 14 stores software modules that provide functionality when executed by processor 22. The modules may include an operating system 15 that provides operating system functionality for apparatus 10. The memory may also store one or more functional modules 18, such as an application or program, to provide additional functionality for apparatus 10. The components of apparatus 10 may be implemented in hardware, or as any suitable combination of hardware and software.

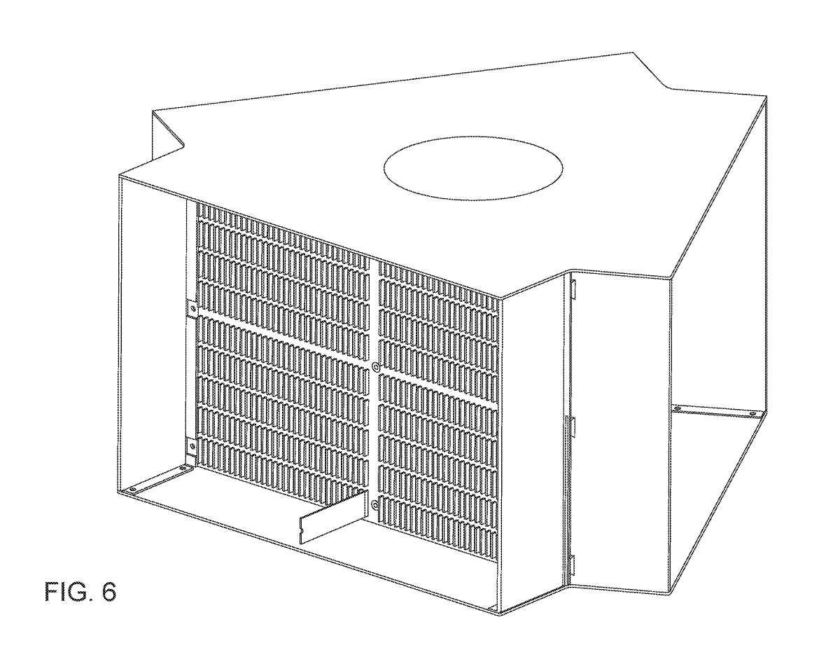

FIG. 6 illustrates another example drive device, in accordance with another embodiment of the present invention. The drive device of FIG. 6 may be configured as a triple-rack, with three open sides. A plurality of memory cards can be secured on each side of the triple-rack. With certain embodiments, one or more fans, and one or more motherboards, can be configured within the enclosure of the drive device to cause airflow to flow outwards from the drive device. With certain embodiments, the drive device may spin/rotate along an axis to dissipate heat and/or to allow a user to have access to the different memory cards. The memory cards of the drive device may be optically-networked.

The described features, advantages, and characteristics of the invention can be combined in any suitable manner in one or more embodiments. One skilled in the relevant art will recognize that the invention can be practiced without one or more of the specific features or advantages of a particular embodiment. In other instances, additional features and advantages can be recognized in certain embodiments that may not be present in all embodiments of the invention. One having ordinary skill in the art will readily understand that the invention as discussed above may be practiced with steps in a different order, and/or with hardware elements in configurations which are different than those which are disclosed. Therefore, although the invention has been described based upon these preferred embodiments, it would be apparent to those of skill in the art that certain modifications, variations, and alternative constructions would be apparent, while remaining within the spirit and scope of the invention.

We claim:

1. An apparatus, comprising:
an enclosure having at least one open side;
a plurality of memory cards secured within the enclosure;
an indicator in communication with the plurality of memory cards; and
a motherboard connected to the plurality of memory cards,
wherein the plurality of memory cards are exposed to the at least one open side, and are suspended over each other, and
wherein the indicator is configured to indicate an operating status of each of the plurality of memory cards.

2. The apparatus of claim 1, further comprising a fan that is disposed within the enclosure, and that is configured to dissipate heat generated by the plurality of memory cards.

3. The apparatus of claim 2, wherein the plurality of memory cards are arranged in a direction that is parallel to an airflow of the fan.

4. The apparatus of claim 1, wherein the indicator is configured to indicate, via lights, whether any of the plurality of need to be replaced.

5. The apparatus of claim 1, wherein the plurality of memory cards include solid-state memory components.

6. The apparatus of claim 1, wherein the plurality of memory cards include memory components, and the memory components comprise m.2 drives.

7. The apparatus of claim 1, further comprising a system status display configured to provide details of an additional operating status of each of the plurality of memory cards, and configured to identify which of the plurality of memory cards has a problem.

8. A system implemented by a drive device, the system comprising:
a plurality of storage devices implemented by a plurality of memory cards;
a switching layer, to which the plurality of storage devices are connected;
a processor layer that is in communication with the switching layer; and
an Ethernet routing functionality that is in communication with the processor layer,
wherein the switching layer and the processor layer are implemented by a motherboard of the drive device, and
wherein the Ethernet routing functionality is configured to enable data to be communicated to and from the plurality of memory cards, and to and from racks of drive devices.

9. The system of claim 8, wherein the plurality of memory cards are solid-state drives.

10. The system of claim 8, wherein the plurality of memory cards are secured in an enclosure of the drive device.

11. The system of claim 8, wherein the drive device comprises an indicator in communication with the plurality of memory cards, and wherein the indicator is configured to indicate an operating status of each of the plurality of memory cards.

12. The system of claim 8, wherein the motherboard is connected to the plurality of memory cards.

13. The system of claim 10, wherein the drive device comprises a fan that is disposed within the enclosure, and that is configured to dissipate heat generated by the plurality of memory cards.

14. The system of claim 13, wherein the plurality of memory cards are arranged in a direction that is parallel to an airflow of the fan.

15. The system of claim 8, wherein the drive device comprises a system status display configured to provide details of an operating status of each of the plurality of memory cards, and configured to identify which of the plurality of memory cards has a problem.
